(19) United States
(12) Patent Application Publication
(10) Pub. No.: US 2026/0118431 A1
(43) Pub. Date: Apr. 30, 2026

(54) INSPECTION JIG FOR ELECTRODE ASSEMBLY, INSPECTION APPARATUS AND METHOD FOR ELECTRODE ASSEMBLY

(71) Applicant: SK On Co., Ltd., Seoul (KR)

(72) Inventor: Jeong Gyu PARK, Daejeon (KR)

(21) Appl. No.: 19/328,260

(22) Filed: Sep. 15, 2025

(30) Foreign Application Priority Data
Oct. 24, 2024 (KR) 10-2024-0146801

(51) Int. Cl. G01R 31/36; G01R 1/04

(52) U.S. Cl. CPC G01R 31/3644; G01R 1/0408

(57) ABSTRACT

The present disclosure relates to an inspection jig for an electrode assembly, an inspection apparatus and method for inspecting an electrode assembly. The inspection jig for an electrode assembly may include: a first jig member including a hollow portion; a second jig member disposed in the hollow portion and pressurizing the electrode assembly in the hollow portion; and a connection portion connected to the first jig member and the second jig member and separating the first jig member and the second jig member, and the connection portion may adjust a separation distance between the first jig member and the second jig member.

### CROSS-REFERENCE TO RELATED APPLICATION(S)

This patent document claims the priority and benefits of Korean Patent Application No. 10-2024-0146801 filed on Oct. 24, 2024, the disclosure of which is incorporated herein by reference in its entirety.

### TECHNICAL FIELD

The present disclosure relates to an inspection jig for an electrode assembly, an inspection apparatus and method for inspecting an electrode assembly.

### BACKGROUND

Batteries are widely used in not only small electronic devices such as mobile phones and laptop computers, but also medium and large mechanical devices such as electric vehicles (EV) and energy storage devices, and have the advantage of being rechargeable and reusable.

An electrode assembly including a cathode plate and an anode plate may be stored in a case selected according to the purpose of use thereof, such as a pouch type, square type, or cylindrical type, and an electrolyte may be injected to manufacture a battery cell.

The electrode assembly may experience a process of inspecting whether there are any foreign substances or impurities mixed during the manufacturing process, and whether there are any defects in the separator.

Inspection of the electrode assembly may be considered to be a significantly decisive process to prevent voltage drops and short circuits in the battery cell in the future.

### SUMMARY

An aspect of the present disclosure is to provide an inspection jig for an electrode assembly capable of detecting a defect in an electrode assembly, an inspection apparatus and a method for inspecting an electrode assembly.

Additionally, the present disclosure may be widely applied to devices within green technology fields such as solar power generation and wind power generation.

Additionally, the present disclosure may be applied to eco-friendly devices such as eco-friendly electric vehicles and hybrid vehicles for ameliorating the effects of climate change by suppressing air pollution and greenhouse gas emissions.

An inspection jig for an electrode assembly according to an embodiment of the present disclosure may include: a first jig member including a hollow portion; a second jig member disposed in the hollow portion and pressurizing the electrode assembly in the hollow portion; and a connection portion connected to the first jig member and the second jig member and separating the first jig member and the second jig member, and the connection portion may adjust a separation distance between the first jig member and the second jig member.

In an embodiment, the second jig member may include: a plurality of second jig plates in contact with an outer surface of the electrode assembly.

In an embodiment, the plurality of second jig plates may cover an outer periphery of the electrode assembly.

In an embodiment, the plurality of second jig plates may be disposed so that an extension line in a diameter direction of an end thereof is oriented in a normal direction of an outer periphery of the electrode assembly.

In an embodiment, the connection portion includes a plurality of connection members connecting the plurality of second jig plates and the first jig member.

In an embodiment, plurality of connection members may be provided in a number equal to the number of the plurality of second jig plates, and one connection member may be connected to one second jig plate.

In an embodiment, the second jig member may include a buffer pad in contact with the electrode assembly.

In an embodiment, the buffer pad may be formed of a material including silicon.

In an embodiment, the connection portion may include a cylinder member in which a piston rod is connected to the first jig member or the second jig member.

In an embodiment, the inspection jig for an electrode assembly may further include: at least one load detection sensor provided between the connection portion and the first jig member.

In an embodiment, the first jig member and the second jig member extend in a height direction of the electrode assembly.

Meanwhile, another aspect of the present disclose is to provide an inspection apparatus of an electrode assembly.

An inspection apparatus of an electrode assembly of an embodiment of the present disclosure may include: an inspection jig for inspecting electrode assembly, including a first jig member including a hollow portion, a second jig member disposed in the hollow portion and pressurizing the electrode assembly in the hollow portion, and a connection portion connected to the first jig member and the second jig member and separating the first jig member and the second jig member, wherein the connection portion adjusts a separation distance between the first jig member and the second jig member; a first grounding member facing one side of the hollow portion and in contact with the first electrode plate of the electrode assembly; a second grounding member facing the other side of the hollow portion and in contact with the second electrode plate of the electrode assembly; and an insulation inspector connected to the first grounding member and the second grounding member.

In an embodiment, the first grounding member may be in contact with a first non-coated region, a region of the first electrode plate on which an electrode active material is not coated, and the second grounding member may be in contact with a second non-coated region, a region of the second electrode plate on which the electrode active material is not coated.

In an embodiment, at least one of the first grounding member and the second grounding member may be circular in a thickness direction cross-section of the electrode assembly.

Meanwhile, another aspect of the present disclosure is to provide a method of inspecting an electrode assembly.

A method of inspecting an electrode assembly, for inspecting the electrode assembly with an inspection apparatus of an electrode assembly including: an inspection jig for inspecting an electrode assembly, including a first jig member including a hollow portion, a second jig member disposed in the hollow portion and pressurizing the electrode assembly in the hollow portion, and a connection portion connected to the first jig member and the second jig member and separating the first jig member and the second jig member, wherein the connection portion adjusts a separation distance between the first jig member and the second jig member; a first grounding member facing one side of the hollow portion and in contact with the first electrode plate of the electrode assembly; a second grounding member facing the other side of the hollow portion and in contact with the second electrode plate of the electrode assembly; and an insulation inspector connected to the first grounding member and the second grounding member, the method comprising: a pressurizing operation of moving the second jig member to the connection portion and pressurizing an outer surface of the electrode assembly with the second jig member; a contact operation of bringing the first grounding member and the second grounding member into contact with the first electrode and the second electrode; and a voltage application operation of applying voltage to the first grounding member and the second grounding member with the insulation inspector.

An aspect of the present disclosure is to provide an inspection jig for an electrode assembly capable of detecting a defect in an electrode assembly, an inspection apparatus and an inspection method for inspecting an electrode assembly.

Additionally, the present disclosure may be widely applied to devices within green technology fields such as solar power generation and wind power generation.

Additionally, the present disclosure may be applied to eco-friendly devices such as eco-friendly electric vehicles and hybrid vehicles for ameliorating the effects of climate change by suppressing air pollution and greenhouse gas emissions.

### BRIEF DESCRIPTION OF DRAWINGS

Certain aspects, features, and advantages of the present disclosure are illustrated by the following detailed description with reference to the accompanying drawings.

FIG. 1 is a schematic diagram illustrating a cross-section of an inspection jig for inspecting an electrode assembly according to an embodiment of the present disclosure.

FIG. 2 is a schematic diagram illustrating an electrode assembly according to an embodiment of the present disclosure.

FIG. 3 is a perspective view schematically illustrating a state in which an electrode assembly is mounted on an inspection jig for inspecting an electrode assembly according to an embodiment of the present disclosure.

FIG. 4 is a schematic diagram illustrating a cross-section of an inspection jig for inspecting an electrode assembly according to another embodiment of the present disclosure.

FIG. 5 is a schematic diagram illustrating a state in which the inspection jig for inspecting the electrode assembly illustrated in FIG. 4 pressurizes the electrode assembly.

FIG. 6 is a schematic diagram illustrating an operation state of an inspection jig for inspecting an electrode assembly according to another embodiment of the present disclosure.

FIG. 7 is a schematic perspective view of an inspection apparatus of an electrode assembly according to an embodiment of the present disclosure.

FIG. 8 is a schematic diagram illustrating an operation state of an inspection apparatus of an electrode assembly according to an embodiment of the present disclosure.

FIG. 9 is a schematic side view of an inspection apparatus for an electrode assembly according to an embodiment of the present disclosure.

FIG. 10 is a schematic illustration of an inspection method for inspecting an electrode assembly according to an embodiment of the present disclosure.

### DETAILED DESCRIPTION

In order to assist in understanding the description of an embodiment of the present disclosure, elements described with the same symbol in the attached drawings are the same elements. Some components in the attached drawings are exaggerated, omitted, or schematically illustrated, and the size of each component does not completely reflect an actual size thereof.

Additionally, in order to clarify the gist of the present disclosure, descriptions of elements and techniques well known by conventional techniques are omitted, and hereinafter, the present disclosure will be described in detail with reference to the attached drawings.

Hereafter, an X-axis illustrated in the drawings is a height direction of an electrode assembly 10, and a Y-axis and a Z-axis are a width direction or a diameter direction of the electrode assembly 10. However, this is a direction arbitrarily set for convenience of understanding, and the directions may be changed.

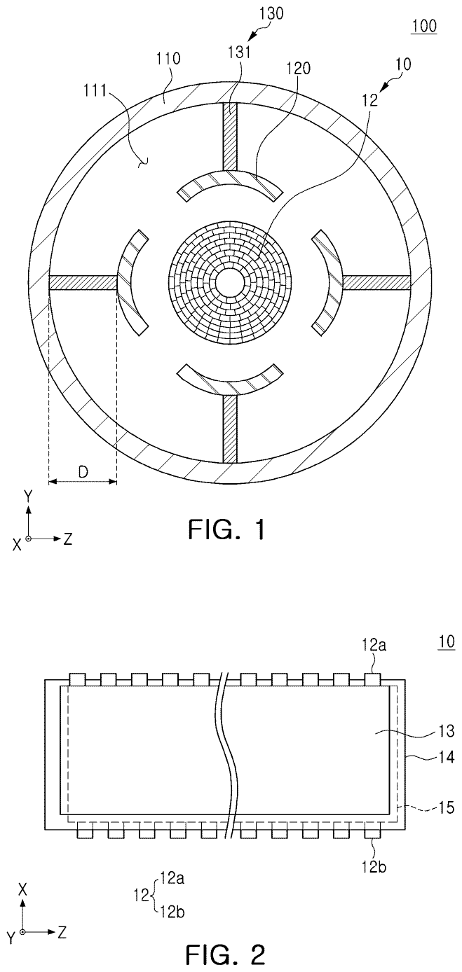

FIG. 1 schematically illustrates a cross-section of an inspection jig 100 of an electrode assembly 10 according to an embodiment of the present disclosure. In FIG. 1, a cross-section of the electrode assembly 10 of the inspection jig 100 of the electrode assembly 10 in the width direction is illustrated, and the electrode assembly 10 is not illustrated in cross-section.

As illustrated in FIG. 1, the inspection jig 100 of the electrode assembly 10 according to an embodiment of the present disclosure may include a first jig member 110 including a hollow portion 111, a second jig member 120 disposed in the hollow portion 111 and pressurizing the electrode assembly 10 in the hollow portion 111, and a connection portion 130 connected to the first jig member 110 and the second jig member 120 and separating the first jig member 110 and the second jig member 120. In this case, the connection portion 130 may adjust a separation distance between the first jig member 110 and the second jig member 120.

The first jig member 110 may have a cylindrical shape. The first jig member 110 may have the hollow portion 111 therein. The hollow portion 111 may extend in a height direction of the electrode assembly 10. The electrode assembly 10 may be accommodated in the hollow portion 111.

A width or diameter of the hollow portion 111 may exceed a width or diameter of the electrode assembly 10. In this case, a width of the electrode assembly 10 may be a maximum width of the electrode assembly 10. A width of the inner diameter of the first jig member 110 may be at least the same as a width of the hollow portion 111.

In an embodiment, the hollow portion 111 may have a cylindrical shape.

The connection portion 130 may be provided on an inner surface of the first jig member 110. The connection portion 130 may extend in a direction oriented toward the second jig member 120.

The second jig member 120 may be disposed in the hollow portion 111 and may surround at least a portion of an outer surface of the electrode assembly 10. The second jig member 120 may be moved in the hollow portion 111 by the connection portion 130.

The second jig member 120 may be moved by the connection portion 130 in a direction away from the outer surface of the electrode assembly 10 or in a direction oriented toward the outer surface of the electrode assembly 10.

The second jig member 120 may be brought into contact with or may be released from contact with the outer surface of the electrode assembly 10.

In an embodiment, when the electrode assembly 10 is accommodated in the hollow portion 111, the connection portion 130 may move the second jig member 120 in a direction oriented toward the inner surface of the first jig member 110. On the other hand, in a state in which the electrode assembly 10 is completely accommodated in the hollow portion 111, the connection portion 130 may move the second jig member 120 in a direction oriented toward the outer surface of the electrode assembly 10, that is, in a direction away from an inner surface of the second jig member 120.

Accordingly, an operation of accommodating the electrode assembly 10 in the hollow portion 111 for inspection of the electrode assembly 10 may be facilitated.

In an embodiment, the second jig member 120 may be spaced apart from the inner surface of the first jig member 110 by a predetermined separation distance D. The connection portion 130 may be disposed between the first jig member 110 and the second jig member 120 to adjust the separation distance D. Accordingly, the second jig member 120 may be easily moved, and the second jig member 120 may be moved to a mounting position of the electrode assembly 10 and a pressurizing position of the electrode assembly 10.

For example, the mounting position of the electrode assembly 10 is a position in which the second jig member 120 is spaced apart from the outer surface of the electrode assembly 10, and the separation distance D in this case may have a minimum value.

The pressurizing position of the electrode assembly 10 is a position in which the second jig member 120 is in contact with the outer surface of the electrode assembly 10, and the separation distance D in this case may have a maximum value.

In some cases, while the electrode assembly 10 is disposed in the hollow portion 111, a position of the second jig member 120 may be a mounting position of the electrode assembly 10, and while performing an inspection of the electrode assembly 10, the position of the second jig member 120 may be a pressurizing position of the electrode assembly 10.

Additionally, in an embodiment, a maximum value of the separation distance D may vary depending on a degree to which the connection portion 130 brings the second jig member 120 into close contact with the electrode assembly 10, or the pressurizing force of the second jig member pressurizing the electrode assembly 10. That is, the maximum value of the separation distance D may increase as the pressurizing force at which the second jig member 120 pressurizes the electrode assembly 10 increases.

Meanwhile, a material of the first jig member 110 and the second jig member 120 may be a material having electrical insulation properties and having a rigidity of a certain level or higher. For example, the first jig member 110 and the second jig member 120 may have a form in which an outer surface of a main body provided with metal is coated with a material having electrical insulation properties.

FIG. 2 schematically illustrates an electrode assembly 10 according to an embodiment of the present disclosure.

As illustrated in FIG. 2, the electrode assembly 10 according to an embodiment of the present disclosure may include at least one first electrode plate 13 having a relatively long length, at least one second electrode plate 15, and at least one separator 14.

For example, the first electrode plate 13 may be a cathode plate, and the second electrode plate 15 may be an anode plate. The cathode plate may be manufactured by applying a cathode active material to a cathode current collector, and the anode plate may be manufactured by applying an anode active material to an anode current collector.

The cathode current collector may be formed of a material including aluminum, stainless steel, nickel, titanium, copper, or alloys thereof. The cathode active material may be in the form of a slurry in which not only the cathode active material but also a binder, a conductive agent, a dispersant, and the like, are mixed and stirred.

The anode current collector may be formed of a material including copper, gold, stainless steel, nickel, aluminum, titanium, or alloys thereof. The anode active material may be in the form of a slurry in which not only the anode active material but also a binder, a conductive agent, a dispersant, and the like, are mixed and stirred.

Additionally, as an example, the cathode current collector and the anode current collector may be provided with a material including a metal such as Co, Mn, or Li.

The separator 14 may be interposed between the first electrode plate 13 and the second electrode plate 15. The separator 14 may separate the first electrode plate 13 and the second electrode plate 15.

The first electrode plate 13 may include a first active material region coated with an electrode active material and a first non-coated region 12a on which the electrode active material is not coated.

The second electrode plate 15 may include a second active material region coated with an electrode active material and a second non-coated region 12b on which the electrode active material is not coated.

The electrode active material coated on the first active material region may be a cathode active material, and the electrode active material coated on the second active material region may be an anode active material.

The first non-coated region 12a may be provided in plural on the first electrode plate 13, and the second non-coated region 12b may be provided in plural on the second electrode plate 15.

The plurality of first blank regions 12a may be formed by notching or punching an edge of the first electrode plate 13, and the plurality of second blank regions 12b may be formed by notching or punching an edge of the second electrode plate 15. However, a forming method is not limited by the present disclosure.

The first electrode plate 13, the second electrode plate 15, and the separator 14 may be provided in plural depending on the case.

In an embodiment, the electrode assembly 10 may have a roll-up type. For example, the first electrode plate 13, the second electrode plate 15, and the separator 14 may be wound in a scroll form in a state of being stacked in the thickness direction (Y-direction) of the first electrode plate 13.

The plurality of first non-coated regions 12a and the plurality of second non-coated regions 12b of the electrode assembly 10 may be bent. The plurality of first non-coated regions 12a may be bent in a direction oriented toward the first electrode plate 13 or the second non-coated region 12b in FIG. 2, and the plurality of second non-coated regions 12b may be bent in a direction oriented toward the second electrode plate 15 or the first non-coated region 12a in FIG. 2. In FIG. 2, the plurality of first non-coated regions 12a and the plurality of second non-coated regions 12b may be bent with a line parallel to the Z-axis as an axis.

As illustrated in FIG. 1 and FIG. 2, the electrode assembly 10 according to an embodiment of the present disclosure may have a circular shape in a cross-section (Y-Z plane) of the electrode assembly 10 in a width direction. For example, the electrode assembly 10 may be an electrode assembly 10 of a cylindrical battery cell. Additionally, for example, the electrode assembly 10 may be an electrode assembly 10 of a tabless type cylindrical battery cell.

In the cylindrical battery cell, a cross-section of the case 11 in which the electrode assembly 10 is accommodated may be circular. However, the type of the battery cell is not limited by the present disclosure.

For example, even in the case of a pouch-type battery cell, after the electrode assembly 10 is wound into a circular shape, the circular electrode assembly 10 may be pressurized to implement a cross-section of the electrode assembly 10 into an oval shape. Accordingly, the inspection jig 100 of the electrode assembly 10 according to an embodiment of the present disclosure may also be applied to the electrode assembly 10 of the pouch-type battery cell. In this manner, an application target of the inspection jig 100 of the electrode assembly 10 is not limited by a final shape of the battery cell to which the electrode assembly 10 is applied.

In an embodiment, the second jig member 120 may include a plurality of second jig plates 121 in contact with the outer surface of the electrode assembly 10.

For example, the number of second jig plates 121 may be four. However, the number is not limited by the present disclosure.

Accordingly, the number of connection portions 130 may also be four, like the second jig plates 121. For example, the number of connection portions 130 and the number of second jig plates 121 may be equal to each other. In this case, one connection portion 130 may move one second jig plate 121. Accordingly, the reliability of an operation of the second jig plate 121 may be improved.

In an embodiment, a plurality of second jig plates 121 may surround or cover an outer periphery of the electrode assembly 10. Or the plurality of second jig plates 121 may enclose an outer periphery of the electrode assembly 10. Accordingly, an entire outer periphery of the electrode assembly 10 may be pressurized by the plurality of second jig plates 121.

If foreign matter is mixed into the electrode assembly 10 during a manufacturing process of the electrode assembly 10, or a pinhole, or the like, is generated in the separator 14, when power source or voltage is applied to the electrode assembly 10, the voltage may be lowered. Additionally, a short circuit of a battery cell equipped with such a defective electrode assembly 10 may be induced.

Accordingly, in a state in which the electrode assembly 10 is pressurized by a certain level, it is necessary to apply voltage to the electrode assembly 10 to inspect a voltage state of the electrode assembly 10. In this case, the reliability of inspection results may be improved as the electrode assembly 10 is pressurized more precisely and uniformly. Accordingly, by uniformly pressurizing the electrode assembly 10 in a circumferential direction of the electrode assembly 10 through a plurality of second jig plates 121, the reliability of the inspection results of the electrode assembly 10 may be improved.

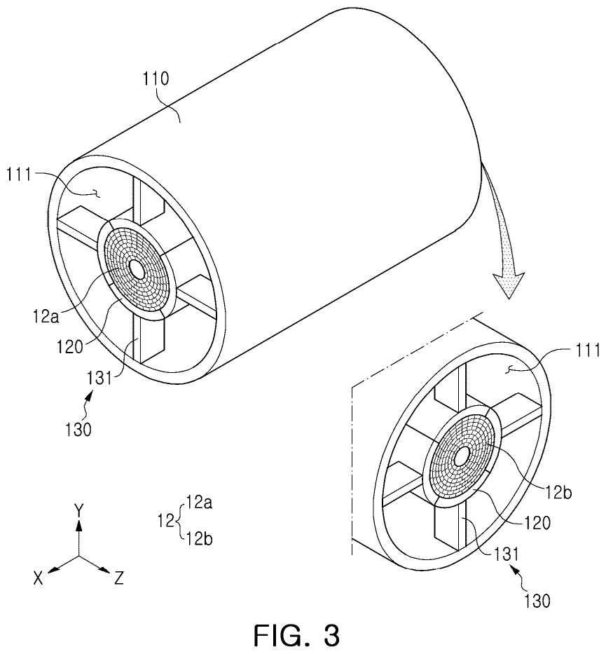

FIG. 3 is a perspective view schematically illustrating a state in which the electrode assembly 10 is mounted on the inspection jig 100 of the electrode assembly 10 according to an embodiment of the present disclosure.

As illustrated in FIGS. 1 to 3, in an embodiment of the present disclosure, the connection portion 130 may include a plurality of connection members 131 connecting the plurality of second jig plates 121 and the first jig member 110.

In an embodiment, the connection member 131 may be a linear motion structure. The linear motion structure may include at least one of a linear bearing, a linear guide, a ball screw, a linear actuator 132, a linear motor 132a, and a linear slide.

The connection member 131 may be provided so that a length of the connection member 131 is longer or shorter. An amount of change in a length of the connection member 131 may be an amount of movement of the electrode assembly 10 of the plurality of second jig plates 121 in a width direction (Z-direction or Y-direction).

In an embodiment, the first jig member 110 may be in a form in which one end (+X-direction) and the other end (−X-direction) in a height direction (X-direction) are open. Accordingly, the electrode assembly 10 may be easily accommodated in the hollow portion 111.

In an embodiment, the plurality of connection members 131 are provided in a number equal to the number of the plurality of second jig plates 121, and one connection member 131 may be connected to one second jig plate 121. For example, the plurality of connection members 131 and the plurality of second jig plates 121 may correspond one to one. Additionally, the plurality of connection members 131 and the plurality of second jig plates 121 may be in one-to-one contact. Accordingly, one connection member 131 may move one second jig plate 121.

Additionally, a length of the first jig member 110 in a longitudinal direction (X-direction) of the electrode assembly 10 may be longer than a length of the electrode assembly 10. For example, the length of the first jig member 110 in the longitudinal direction (X-direction) of the electrode assembly 10 may be equal to the length of the electrode assembly 10.

Additionally, in an embodiment, the first jig member 110 and the second jig member 120 may extend in a height direction (X-direction) of the electrode assembly 10. Accordingly, the electrode assembly 10 may be uniformly pressurized in a width direction and a length direction. In this case, the connection portion 130 may also extend in the height direction (X-direction) of the electrode assembly 10.

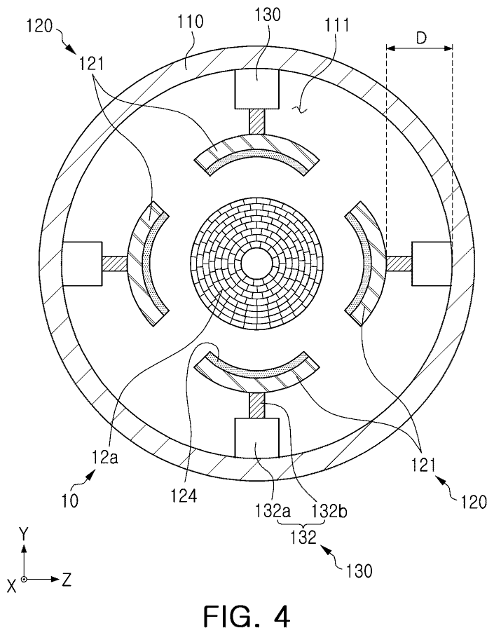

FIG. 4 schematically illustrates a cross-section of an inspection jig 100 of an electrode assembly 10 according to another embodiment of the present disclosure.

As illustrated in FIG. 4, in an embodiment of the present disclosure, the second jig member 120 may include a buffer pad 124 in contact with the electrode assembly 10.

In the case in which the second jig member 120 includes a plurality of second jig plates 121, the buffer pad 124 may be provided on each of the plurality of second jig plates 121.

The buffer pad 124 may be in contact with the outer surface of the electrode assembly 10. In this case, a separator 14 may be disposed on the outer surface of the electrode assembly 10. The buffer pad 124 may be in contact with the separator 14. In some cases, the separator 14 may be fixed with a tape or the like.

The buffer pad 124 may be a material having electrical insulation.

In an embodiment, the buffer pad 124 may be formed of a material including silicon. Accordingly, scratches, damage, or the like, on the electrode assembly 10 may be minimized or prevented. Additionally, by applying the buffer pad 124 with silicone, the buffer pad 124 may absorb the roughness of the outer surface of the electrode assembly 10. Accordingly, the pressurization efficiency of the electrode assembly 10 may be improved. However, the material of the buffer pad 124 may be changed.

Additionally, in an embodiment of the present disclosure, the connection portion 130 may include an actuator 132. In an embodiment, the actuator 132 may be implemented as a combination of a motor 132a and a driving rod 132b.

The motor 132a may provide driving force and may be fixed to the inner surface of the first jig member 110. One side of the driving rod 132b may be connected to a rotational shaft of the motor 132a through at least one gear capable of converting a rotational motion of the motor 132a into linear motion. The other side of the driving rod 132b may be connected to the second jig member 120. Accordingly, a length of the driving rod 132b may be changed by the rotation of the motor 132a.

In some cases, the length of the driving rod 132b may be lengthened or shortened depending on a rotational direction of the rotational shaft of the motor 132a. Accordingly, the separation distance D may be changed.

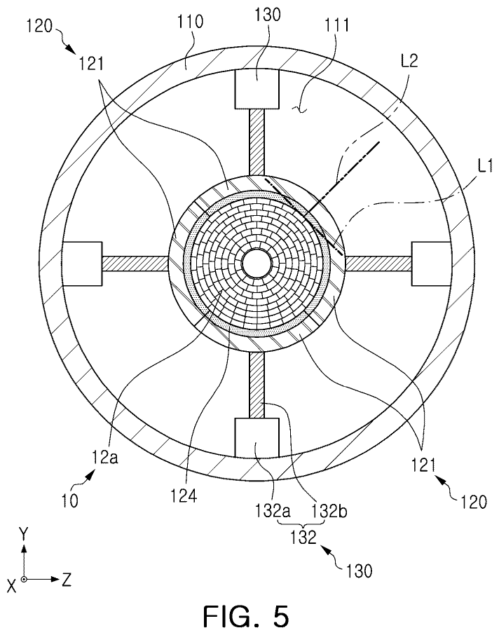

FIG. 5 schematically illustrates a state in which the inspection jig 100 of f the electrode assembly 10 illustrated in FIG. 4 pressurizes the electrode assembly 10.

As illustrated in FIG. 5, in a state in which a plurality of second jig plates 121 pressurize the electrode assembly 10, ends of the plurality of second plates may be in contact with each other. In a state in which the ends of the plurality of second plates are in contact with each other, outer lines of the plurality of second jig plates 121 may be circular.

Additionally, in an embodiment, the plurality of second jig plates 121 may be disposed so that an extension line L2 in a diametric direction of the first jig member 110 or a diametric direction of the second jig member 120 of the ends is oriented in a normal direction of the outer periphery of the electrode assembly 10.

For example, the plurality of second jig plates 121 may be disposed so that the extension line L2 in the diametric direction of the first jig member 110 or the diametric direction of the second jig member 120 of the ends is oriented in a normal direction of a tangent line L1 of the outer periphery of the electrode assembly 10.

Accordingly, when the plurality of second jig plates 121 pressurize the electrode assembly 10, ends of the plurality of second jig plates 121 may be in contact with each other, and outer lines of the plurality of second jig plates 121 may become circular in a state in which the ends of the plurality of second jig plates 121 are in contact with each other. Accordingly, unnecessary interference between the plurality of second jig plates 121 may be eliminated.

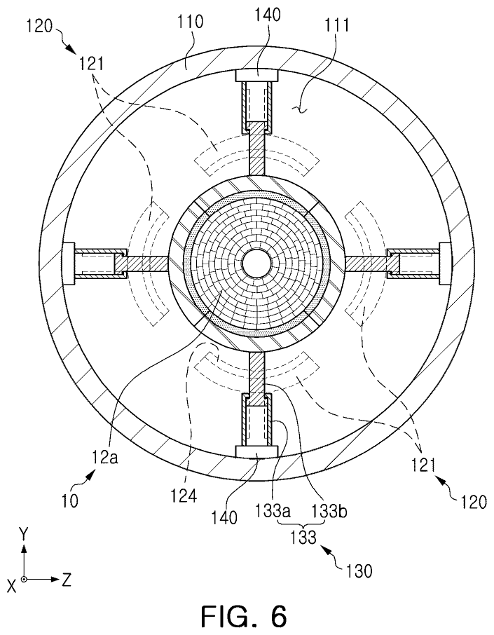

FIG. 6 is a schematic operating state diagram of an inspection jig 100 of an electrode assembly 10 according to another embodiment of the present disclosure.

As illustrated in FIG. 6, in an embodiment of the present disclosure, the connection portion 130 may include a cylinder member 133 in which a piston rod 133b is connected to the first jig member 110 or the second jig member 120.

In an embodiment, in the cylinder member 133, a body 133a may be fixed to an inner surface of the first jig member 110, and one end of the piston rod 133b may be connected to the second jig member 120. For example, the cylinder member 133 may be a hydraulic cylinder operating by hydraulic pressure. Accordingly, a length of the piston rod 133b may be changed by adjusting the hydraulic pressure.

Additionally, in an embodiment of the present disclosure, at least one load detection sensor 140 may be provided between the connection portion 130 and the first jig member 110.

For example, the load detection sensor 140 may be a load cell. However, a type of the load detection sensor 140 is not limited by the present disclosure.

In the case in which the connection portion 130 is a cylinder member 133, the load detection sensor 140 may be disposed between the body 133a and the inner surface of the first jig member 110. However, an installation location of the load detection sensor 140 may be changed. Accordingly, the pressure applied to the electrode assembly 10 may be easily identified.

In an embodiment, the load detection sensor 140 may be provided in plural, and the plurality of load detection sensors 140 may be respectively connected to a plurality of connection potions 130. Accordingly, the pressure applied to the electrode assembly 10 may be easily identified in multiple directions.

Accordingly, the reliability of the test results of the electrode assembly, including a current test, a voltage test, and a short-circuit test of the electrode assembly, may be improved.

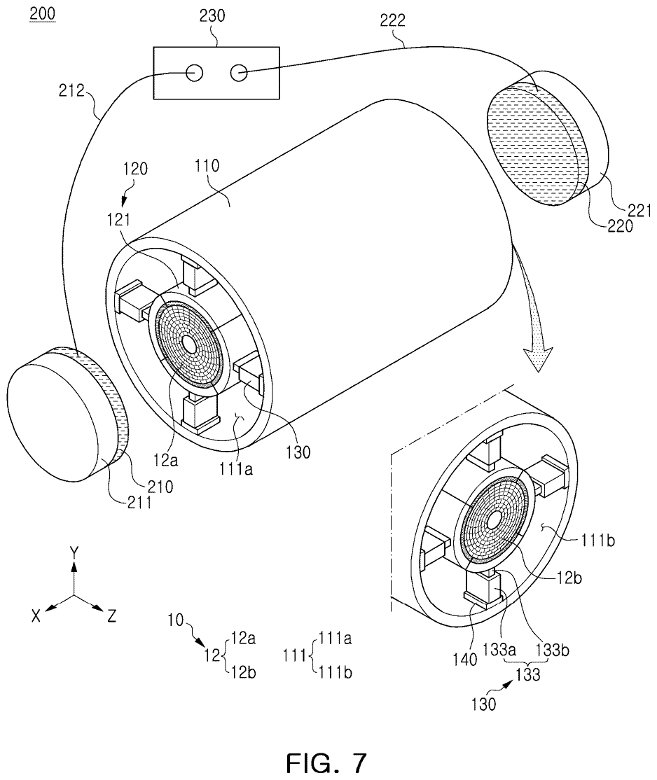

Meanwhile, as another aspect, the present disclosure provides an inspection apparatus 200 for an electrode assembly to inspect an electrode assembly 10 with an inspection jig 100 of an electrode assembly 10. FIG. 7 is a schematic perspective view of an inspection apparatus 200 for an electrode assembly according to an embodiment of the present disclosure.

The inspection apparatus 200 for an electrode assembly may inspect an electrode assembly 10 with an inspection jig 100 of an electrode assembly 10 according to any one of the above-described embodiments or a combination of embodiments. Additionally, the electrode assembly 10 may be inspected with an inspection jig 100 of another electrode assembly 10.

For example, an inspection of the electrode assembly 10 may be at least one of a short test, a voltage test, a current test or an insulation test. Additionally, for example, the inspection of the electrode assembly 10 may be a Hipot test. The Hipot inspection is a test for checking the current flowing from one point to another point by applying a high voltage to a cathode terminal and an anode terminal of the electrode assembly 10 or a battery cell including the electrode assembly 10. Through the inspection, it may be possible to check whether the current flows above a certain value.

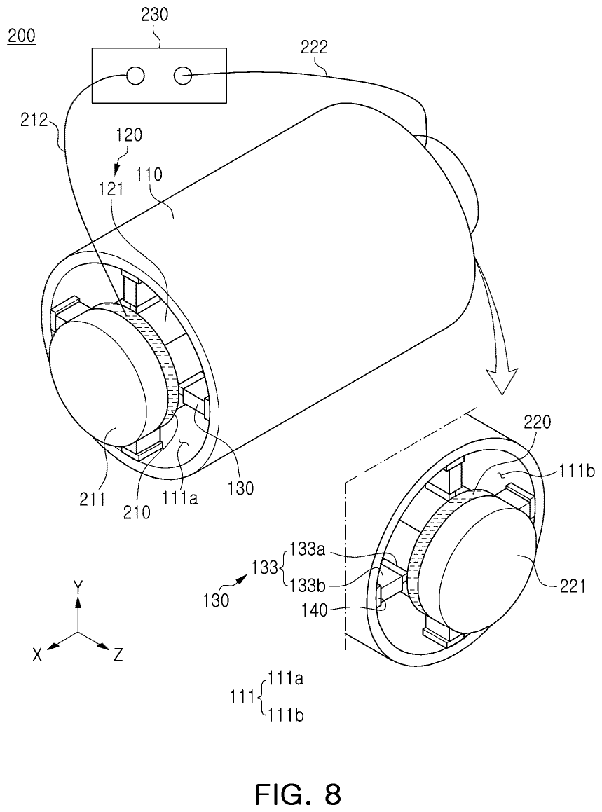

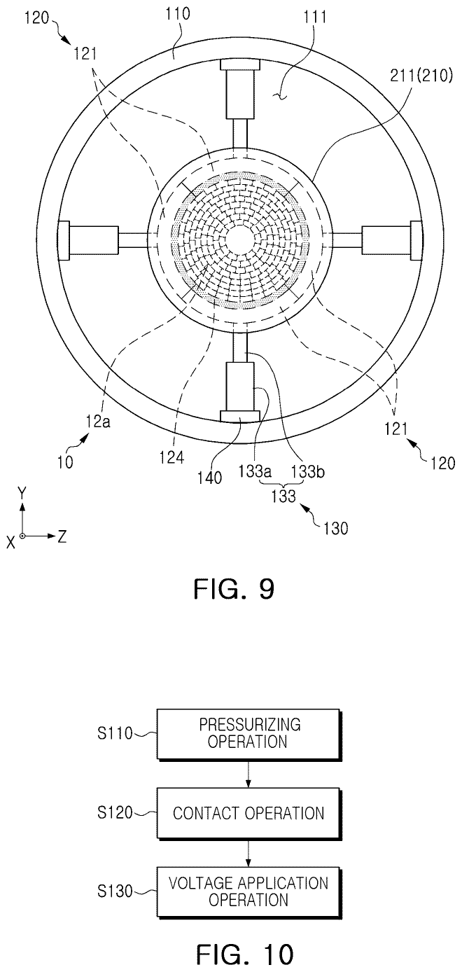

FIG. 8 is a schematic operation state diagram of an electrode assembly inspection apparatus 200 according to an embodiment of the present disclosure, and FIG. 9 is a schematic side view of an electrode assembly inspection apparatus 200 according to an embodiment of the present disclosure.

As illustrated in FIGS. 7 to 9, an embodiment of the present disclosure provides an inspection apparatus 200 of an electrode assembly including: an inspection jig 100 of the electrode assembly 10 including a first jig member 110 including a hollow portion 111, a second jig member 120 disposed in the hollow portion 111 and pressurizing the electrode assembly 10 in the hollow portion 111, and a connection portion 130 connected to the first jig member 110 and the second jig member 120 and separating the first jig member 110 and the second jig member 120, wherein the connection portion 130 adjusts a separation distance between the first jig member 110 and the second jig member 120; a first grounding member 210 facing one side of the hollow portion 111 and in contact with the first electrode plate 13 of the electrode assembly 10; a second grounding member 220 facing the other side of the hollow portion 111 and in contact with the second electrode plate 15 of the electrode assembly 10; and an insulation inspector 230 connected to the first grounding member 210 and the second grounding member 220.

The insulation inspector 230 may be a device connected to the electrode assembly 10 to measure resistance and/or current. The insulation inspector 230 may apply voltage to the electrode assembly 10.

The first grounding member 210 and the second grounding member 220 may be formed of a material having electrical conductivity. The insulation inspector 230 may be connected to the first grounding member 210 by a first line 212 and may be connected to the second grounding member 220 by a second line 222.

Each of the first grounding member 210 and the second grounding member 220 may be in contact with electrode plates having different polarities in the electrode assembly 10. The first line 212 and the second line 222 may be electrically conductive wires, and may be connected to the insulation inspector 230 or may be accessories of the insulation inspector 230.

Meanwhile, as illustrated in FIGS. 2, 8 and 9, in an embodiment of the present disclosure, the first grounding member 210 may be in contact with the first non-coated region 12a, a region of the first electrode plate 13 on which the electrode active material is not coated, and the second grounding member 220 may be in contact with the second non-coated region 12b, a region of the second electrode plate 15 on which the electrode active material is not coated.

For example, as illustrated in FIGS. 1, 2, 8 and 9, in the first grounding member 210, at least one surface thereof may be in contact with the plurality of first non-coated regions 12a in a state in which the plurality of first non-coated regions 12a are bent. Additionally, in the second grounding member 220, at least one surface thereof may be in contact with the plurality of second non-coated regions 12b in a state in which the plurality of second non-coated regions 12b are bent.

In an embodiment, the hollow portion 111 of the first jig member 110 may include a first open region 111a and a second open region 111b. The first open region 111a may be a region opened in one end of the first jig member 110, and the second open region 111b may be a region opened in the other end of the first jig member 110.

The first grounding member 210 may be in contact with the electrode assembly 10 in the first open region 111a, and the second grounding member 220 may be in contact with the electrode assembly 10 at the second open region 111b.

In an embodiment, the first grounding member 210 may be supported by a first support member 211, and the second grounding member 220 may be supported by a second support member 221. The first grounding member 210 may be fixed to the first support member 211, and the second grounding member 220 may be fixed to the second support member 221.

The first support member 211 and the second support member 221 may be formed of a material having electrical insulation properties. Accordingly, electrical interference with external factors that inspect the electrode assembly 10 may be eliminated or minimized.

The insulation inspector 230 may be controlled by a user, and the user may control the insulation inspector 230 so that a power source is applied to the electrode assembly 10 when the second jig plate 121 has completed pressurizing the electrode assembly 10.

Additionally, the user may monitor the load detection sensor 140 to check pressurizing force applied to the electrode assembly 10.

In this case, when a deviation in the pressurizing force occurs, the intensity of the pressurizing force applied to a specific region of the electrode assembly 10 may be adjusted by individually controlling a plurality of second jig plates 121. This may contribute to increasing the inspection reliability of the electrode assembly 10.

Additionally, in an embodiment, at least one of the first grounding member 210 and the second grounding member 220 in a thickness direction cross-section (Y-Z plane) of the electrode assembly 10 may be circular.

For example, in the thickness direction cross-section Y-Z plane of the electrode assembly 10, at least one of an outer line of the first grounding member 210 and an outer line of the second grounding member 220 may be circular. Accordingly, when the electrode assembly 10 is circular, the first grounding member 210 and the second grounding member 220 may be uniformly contacted with the electrode assembly 10 and may be easily contacted therewith.

Accordingly, the reliability of the inspection results of the electrode assembly, including a current test, a voltage test, a short-circuit test, and the like, of the electrode assembly, may be improved.

FIG. 10 schematically illustrates a method of inspecting an electrode assembly according to an embodiment of the present disclosure.

The inspection method of the electrode assembly may inspect the electrode assembly 10 using an inspection apparatus 200 of the electrode assembly according to any one of the above-described embodiments or a combination of embodiments. Alternatively, the electrode assembly 10 may be inspected using an inspection apparatus 200 of another electrode assembly.

As illustrated in FIGS. 1 to 10, an embodiment of the present disclosure provides a method of inspecting an electrode assembly, for inspecting the electrode assembly 10 with the inspection apparatus 200 of an electrode assembly including: an inspection jig 100 of the electrode assembly 10, including a first jig member 110 including a hollow portion 111, a second jig member 120 disposed in the hollow portion 111 and pressurizing the electrode assembly 10 in the hollow portion 111, and a connection portion 130 connected to the first jig member 110 and the second jig member 120 and separating the first jig member 110 and the second jig member 120, wherein and the connection portion 130 adjusts a separation distance between the first jig member 110 and the second jig member 120; and including: a first grounding member 210 facing one side of the hollow portion 111 and in contact with a first electrode plate 13 of the electrode assembly 10; a second grounding member 220 facing the other side of the hollow portion 111 and in contact with the second electrode plate 15 of the electrode assembly 10; and an insulation inspector 230 connected to the first grounding member 210 and the second grounding member 220, the method including: a pressurizing operation (S110) of moving the second jig member 120 to the connection portion 130 and pressurizing an outer surface of the electrode assembly 10 with the second jig member 120, a contact operation (S120) of bringing the first electrode and the second electrode into contact with the first electrode and the second electrode, and a voltage application operation (S130) of applying voltage to the first grounding member 210 and the second grounding member 220 with the insulation inspector 230.

The pressurizing operation (S110) may be performed by adjusting the second jig member 120 with the connection portion 130. A separation distance D in the pressurizing step (S110) may be changed.

The contact operation (S120) may be performed after the pressurizing operation (S110) is completed, or may be performed before the pressurizing operation (S110) or simultaneously with the pressurizing operation (S110).

The voltage application operation (S130) may be performed after the pressurizing operation (S110) is completed. Accordingly, the electrode assembly 10 may be inspected in a state in which the electrode assembly 10 is uniformly pressurized in a center direction of the electrode assembly 10. Accordingly, the reliability of the inspection results of the electrode assembly, including a current test, a voltage test, a short-circuit test, and the like, of the electrode assembly, may be improved.

The contents described above are merely examples of applying the principles of the present disclosure, and other components may be further included or substituted and applied within a scope that does not exceed the scope of the present disclosure. Additionally, the present disclosure may be implemented by deleting or changing some of the components in the above-described embodiments, and each embodiment may be implemented in combination with each other.

What is claimed is:

1. An inspection jig for an electrode assembly, comprising:
a first jig member including a hollow portion;
a second jig member disposed in the hollow portion and pressurizing the electrode assembly in the hollow portion; and
a connection portion connected to the first jig member and the second jig member and separating the first jig member and the second jig member,
wherein the connection portion adjusts a separation distance between the first jig member and the second jig member.

2. The inspection jig for an electrode assembly of claim 1, wherein the second jig member includes:
a plurality of second jig plates in contact with an outer surface of the electrode assembly.

3. The inspection jig for an electrode assembly of claim 2, wherein the plurality of second jig plates cover an outer periphery of the electrode assembly.

4. The inspection jig for an electrode assembly of claim 2, wherein the plurality of second jig plates are disposed so that an extension line in a diameter direction of an end thereof is oriented in a normal direction of an outer periphery of the electrode assembly.

5. The inspection jig for an electrode assembly of claim 2, wherein the connection portion includes a plurality of connection members connecting the plurality of second jig plates and the first jig member.

6. The inspection jig for an electrode assembly of claim 5, wherein the plurality of connection members are provided in a number equal to the number of the plurality of second jig plates, and
one connection member is connected to one second jig plate.

7. The inspection jig for an electrode assembly of claim 1, wherein the second jig member includes a buffer pad in contact with the electrode assembly.

8. The inspection jig for an electrode assembly of claim 7, wherein the buffer pad is formed of a material including silicon.

9. The inspection jig for an electrode assembly of claim 1, wherein the connection portion includes a cylinder member in which a piston rod is connected to the first jig member or the second jig member.

10. The inspection jig for an electrode assembly of claim 1, further comprising:
at least one load detection sensor provided between the connection portion and the first jig member.

11. The inspection jig for an electrode assembly of claim 1, wherein the first jig member and the second jig member extend in a height direction of the electrode assembly.

12. An inspection apparatus of an electrode assembly, comprising:
an inspection jig for inspecting an electrode assembly, including a first jig member including a hollow portion, a second jig member disposed in the hollow portion and pressurizing the electrode assembly in the hollow portion, and a connection portion connected to the first jig member and the second jig member and separating the first jig member and the second jig member, wherein the connection portion adjusts a separation distance between the first jig member and the second jig member;
a first grounding member facing one side of the hollow portion and in contact with the first electrode plate of the electrode assembly;
a second grounding member facing the other side of the hollow portion and in contact with the second electrode plate of the electrode assembly; and
an insulation inspector connected to the first grounding member and the second grounding member.

13. The inspection apparatus of an electrode assembly of claim 12, wherein the first grounding member is in contact with a first non-coated region, a region of the first electrode plate on which an electrode active material is not coated, and
the second grounding member is in contact with a second non-coated region, a region of the second electrode plate on which the electrode active material is not coated.

14. The inspection apparatus of an electrode assembly of claim 12, wherein at least one of the first grounding member and the second grounding member is circular in a thickness direction cross-section of the electrode assembly.

15. A method of inspecting an electrode assembly, for inspecting the electrode assembly with an inspection apparatus of an electrode assembly including: an inspection jig for inspecting an electrode assembly, including a first jig member including a hollow portion, a second jig member disposed in the hollow portion and pressurizing the electrode assembly in the hollow portion, and a connection portion connected to the first jig member and the second jig member and separating the first jig member and the second jig member, wherein the connection portion adjusts a separation distance between the first jig member and the second jig member; a first grounding member facing one side of the hollow portion and in contact with the first electrode plate of the electrode assembly; a second grounding member facing the other side of the hollow portion and in contact with the second electrode plate of the electrode assembly; and an insulation inspector connected to the first grounding member and the second grounding member, the method comprising:
a pressurizing operation of moving the second jig member to the connection portion and pressurizing an outer surface of the electrode assembly with the second jig member;
a contact operation of bringing the first grounding member and the second grounding member into contact with the first electrode and the second electrode; and
a voltage application operation of applying voltage to the first grounding member and the second grounding member with the insulation inspector.
